(19) United States
(12) Patent Application Publication
(10) Pub. No.: US 2011/0097897 A1
(43) Pub. Date: Apr. 28, 2011

(54) METHOD FOR MANUFACTURING SEMICONDUCTOR DEVICE

(75) Inventor: Katsuhiko TANAKA, Tokyo (JP)

(73) Assignee: ELPIDA MEMORY, INC, Tokyo (JP)

(21) Appl. No.: 12/908,361

(22) Filed: Oct. 20, 2010

(30) Foreign Application Priority Data
Oct. 23, 2009 (JP) 2009-244321

(51) Int. Cl. H01L 21/768

(52) U.S. Cl. 438/653; 257/E21.584

(57) ABSTRACT

A method for manufacturing a semiconductor device, including: forming a barrier seed Ti layer covering a recess in an insulating film; forming a first barrier TiN layer by sputtering; forming a second barrier TiN layer by sputtering with a substrate bias power higher than that in forming the first barrier TiN layer; forming a first wiring seed Ti layer by sputtering; forming a second wiring seed Ti layer by sputtering with a substrate bias power higher than that in forming the first wiring seed Ti layer; forming a first wiring seed Al layer by sputtering; forming a second wiring seed Al layer by sputtering with a substrate bias power higher than that in forming the first wiring seed Al layer; forming Ti—Al alloy in the recess by a heating; and forming an Al wiring material layer so as to fill the recess therewith by sputtering and heating.

### BACKGROUND OF THE INVENTION

1. Field of the Invention

The present invention relates to a method for manufacturing a semiconductor device.

2. Description of Related Art

In a technique field of the method for manufacturing a semiconductor device, as the semiconductor device becomes more and more minimized, a diameter of an aperture of a through-hole used in forming a via plug becomes smaller, accordingly an aspect ratio of the via hole being higher. Because of this, a variety of techniques have been studied for forming a thin film within the through-hole or filling the hole with conductive material.

In Japanese patent laid-open No. 2008-45219, a method is disclosed in which a base thin film made of aluminum is formed at inner walls of a hole by ionization sputtering method below 150° C. and, thereafter, the hole is filled with aluminum by performing a sputtering to form an aluminum film and, at the same time, performing a reflowing of the formed aluminum film at 300° C.

In Japanese patent laid-open No. 2004-107688, a bias sputtering film-forming method is disclosed in which in order to form a barrier layer or a seed layer for electrolysis plating, a thin film is formed with applying only a cathode voltage and, next, a sputtering film-formation is performed together with changing a substrate bias so that a thickness of the formed film is uniform.

In Japanese patent laid-open No. 2004-153162, a bias sputtering film-forming method is disclosed which forms, with superior coverage, a barrier film (Ta film) to copper (Cu) within a via hole having a high aspect ratio. In this film-forming method, a first sputtering step is performed with a low RF bias (preferably, non-bias) to form Ta film and, then, a second sputtering step is performed, with a higher RF bias than that in the first sputtering step, under the condition that a first state in which Ta film is caused to be deposited and a second state in which the deposited Ta film is etched away coexist and the first state is made higher in strength than the second state. In addition, a three-step sputtering for forming the barrier film is disclosed which includes a first sputtering step with a low RF bias, a second sputtering step which is performed under the condition that the second state is made higher in strength than the first state, and a third sputtering step with a lower RF bias than that in the second sputtering step.

In Japanese patent laid-open No. 2005-285820, a bias sputtering film-forming method is disclosed which is performed to form, with good coverage, a barrier film (Ta film) to Cu or a seed layer for electrolysis plating within a trench or hole with a small size. This method includes a first step of applying only a cathode voltage or applying the cathode voltage and a tenuous substrate bias voltage to form Ta film in an interior (in particular, a bottom) of the hole, and a second step of applying a cathode voltage smaller than the cathode voltage applied at the first step and, at the same time, changing a substrate bias voltage so that a thickness of a thin film within the hole becomes a desired size. This document discloses that in the second step, a rate at which a bottom covering film is formed is reduced by decreasing the cathode voltage and an etching rate is remarkably enhanced by increasing the substrate bias voltage. This document also discloses that overhangs are prevented from being formed at an aperture of the hole or the like by injecting sputtered particles at a substantially 90° angle and, hence, considerable amount of the film deposited at the bottom of the hole can be obtained, and, in turn, formation of a film at the side wall of the hole can be, without damaging a base film, reliably performed by carrying out the bias sputtering film formation using the deposited bottom film as a film forming source.

### SUMMARY

It has been apparent to the inventor of the present invention that in a following method for filling a hole with aluminum by sputtering and reflow methods, if a diameter of an aperture of the hole becomes smaller, there occur following problems.

A hole is formed in an interlayer insulating film so as to reach a copper wiring layer and, then, a barrier seed layer made of Ti, a barrier layer made of TiN and a wiring seed Ti layer made of Ti are formed in the order described, to cover an interior of the hole. Because at this time, coverage is low, an overhang made of the barrier layer is formed at the aperture of the hole and, hence, it is difficult for the barrier layer to be further formed in the interior of the hole, so that a thickness of the bottomed barrier layer (TiN layer) which is formed at the bottom of the hole turns out small. As the same way, a thickness of the wiring seed Ti layer formed on the bottomed barrier layer turns out small. Subsequently, a wiring seed Al layer made of aluminum is formed on the wiring seed Ti layer by a sputtering method and the resultant structure is subjected to a thermal treatment at 380 to 450° C. during 30 to 120 seconds, and, thus, Ti of the wiring seed Ti layer is diffused into the wiring seed Al layer, thereby generating Ti—Al alloy particles composed of Ti and Al. Because this alloy particle is wetted to Al very well, Al is easily filled into the hole having a high aspect ratio. However, because the bottomed wiring seed Ti layer is thin as mentioned above, a reaction between this bottomed wiring seed Ti layer and the wiring seed Al layer is insufficient, so that quantity of the generated Ti—Al alloy particles is small and the generated Ti—Al alloy particles have irregular distribution.

Thereafter, a reflow Al layer made of Al is formed on the wiring seed Al layer by performing a sputtering method together with heating a substrate (i.e. a reflow sputtering method). Such a reflow Al layer are integrated with the wring seed Al layer to form Al wiring. Because at this time, quantity of the generated Ti—Al alloy particles in the hole (in particular, at the bottom of the hole) is small and the generated Ti—Al alloy particles have irregular distribution, the hole is insufficiently filled with the reflow Al layer. Further, because the bottomed barrier layer (TiN layer) is thin, Al and Cu interdiffuse with passing between TiN crystal particles of the thin TiN layer, thereby generating Al—Cu alloy having large electrical resistance. The resultant structure is shown in FIG. 1. In this figure, reference numeral 1 denotes a semiconductor substrate, reference numeral 2 denotes an interlayer insulating layer, reference numeral 3 denotes Cu wiring, reference numeral 4 denotes an interlayer insulating layer, reference numeral 5 denotes a barrier seed layer (Ti layer), reference numeral 6 denotes a barrier layer (TiN layer), reference numeral 6a denotes an overhang, reference numeral 9 denotes Ti—Al alloy particle, reference numeral 11 denotes Al wiring, and reference numeral 101 denotes Al—Cu alloy. In this figure, the wiring seed Ti layer and the wiring seed Al layer are omitted. Although Ti—Al alloy particles 9 are shown as uniformly circular and exist at the bottom of the hole as well in the figure, Ti—Al alloy particles 9, in practice, have rock-shaped indeterminate forms and non-uniform sizes, and are generated with small quantity at the bottom of the hole.

The generation of the Al—Cu alloy causes a wiring delay. Moreover, when Al and Cu further interdiffuse, the hole is insufficiently filled and, in addition, cavities are formed in the Cu wiring and the Al wiring, resulting in bad electrical conductance. Because such a phenomenon will continue and be enlarged by thermal treatments in subsequent processes, the problem becomes more malignant.

In one embodiment, there is provided a method for manufacturing a semiconductor device, including:

forming a recess in an insulating film on a substrate;

forming a barrier seed Ti layer covering an inner wall of the recess;

forming, by a sputtering, a first barrier TiN layer covering the barrier seed Ti layer in the recess;

forming a second barrier TiN layer on the first barrier TiN layer by a sputtering with a substrate bias power higher than a substrate bias power used in forming the first barrier TiN layer;

forming, by a sputtering, a first wiring seed Ti layer covering the second barrier TiN layer in the recess;

forming a second wiring seed Ti layer on the first wiring seed Ti layer by a sputtering with a substrate bias power higher than a substrate bias power used in forming the first wiring seed Ti layer;

forming, by a sputtering, a first wiring seed Al layer covering the second wiring seed Ti layer in the recess;

forming a second wiring seed Al layer on the first wiring seed Al layer by a sputtering with a substrate bias power higher than a substrate bias power used in forming the first wiring seed Al layer;

forming, by a heating, Ti—Al alloy on the second barrier TiN layer in the recess; and

forming an Al wiring material layer covering the recess so as to fill the recess with the Al wiring material layer by sputtering and heating for reflowing the Al wiring material layer.

According to an embodiment, the small recess can be reliably filled with the Al wiring material.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows a schematic cross-sectional view for illustrating a problem which a related prior-art has;

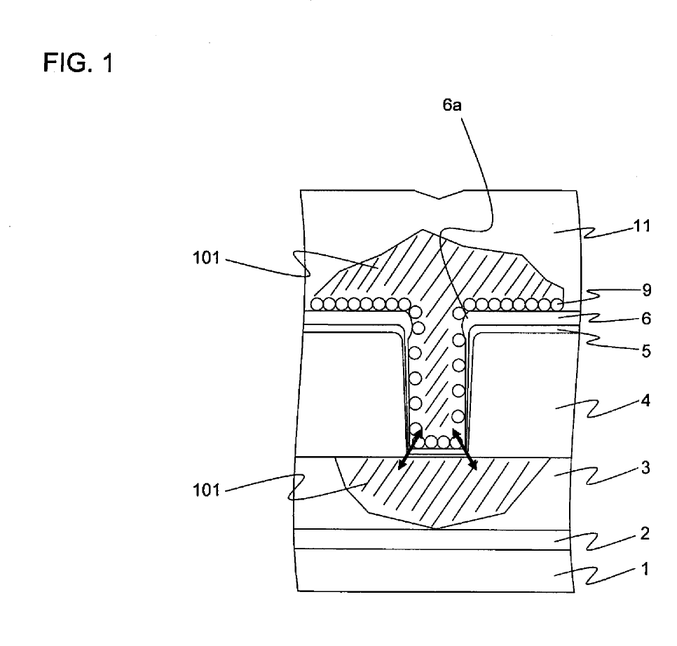

FIG. 2 shows a cross-sectional view of a structure resulting from a step of a manufacturing method according to an exemplary embodiment of the present invention;

FIG. 3 shows a cross-sectional view of a structure resulting from a step following the step of manufacturing the structure shown in FIG. 2;

FIG. 4 shows a cross-sectional view of a structure resulting from one step following the step of manufacturing the structure shown in FIG. 3;

FIG. 5 shows a cross-sectional view of a structure resulting from a step following the step of manufacturing the structure shown in FIG. 4;

FIG. 6 shows a cross-sectional view of a structure resulting from a step following the step of manufacturing the structure shown in FIG. 5;

FIG. 7 shows a cross-sectional view of a structure resulting from a step following the step of manufacturing the structure shown in FIG. 6;

FIG. 8 shows a cross-sectional view of a structure resulting from a step following the step of manufacturing the structure shown in FIG. 7;

FIG. 9 shows a cross-sectional view of a structure resulting from a step following the step of manufacturing the structure shown in FIG. 8;

FIG. 10 shows a cross-sectional view of a structure resulting from a step following the step of manufacturing the structure shown in FIG. 9;

FIG. 11 shows a cross-sectional view of a structure resulting from a step following the step of manufacturing the structure shown in FIG. 10; and

FIG. 12 shows a plan view for illustrating a film-forming apparatus used in the manufacturing method according to an exemplary embodiment of the present invention.

### DETAILED DESCRIPTION OF PREFERRED EMBODIMENTS

In the following, an exemplary embodiment of the present invention will be described in details.

First, an element isolation region such as STI (Shallow Trench Isolation) is formed in a semiconductor substrate (a wafer with 300 mm of a diameter) and, then, a gate electrode is formed on an active region partitioned by the element isolation region, and, next, diffusion layers are formed by implanting impurities. In this usual way, a transistor is formed. Thereafter, interlayer insulating film 2 is formed and, subsequently, copper wiring 3 is formed on interlayer insulating film 2. Copper wiring 3 is electrically connected to the transistor through a plug penetrating interlayer insulating film 2, the plug being made of such as tungsten (W).

Subsequently, interlayer insulating film 4 made of such as a silicon oxidation film (SiO₂) is formed over Cu wiring 3 by PE-CVD (Plasma Enhanced-Chemical Vapor Deposition).

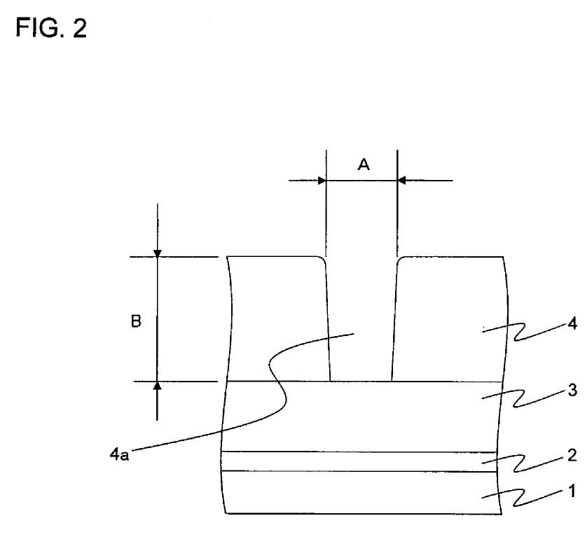

Thereafter, as shown in FIG. 2, through-hole 4a is formed in interlayer insulating film 4 so as to reach Cu wiring 3 by photolithography and dry etching techniques. Here, a diameter (A) of an aperture of through-hole 4a can be set to a value equal to or less than 0.5 μm, a depth (B) of through-hole 4a can be set to a value equal to or less than 2.5 μm, and an aspect ratio (B/A) of through-hole 4a can be set within a rage of 1 to 5.

Then, as a treatment before a film-formation, a natural oxidation film formed on a region of Cu wiring 3 which is exposed as an bottom of through-hole 4a is removed by performing an annealing, for example, under a hydrogen atmosphere at 300° C. during 60 seconds.

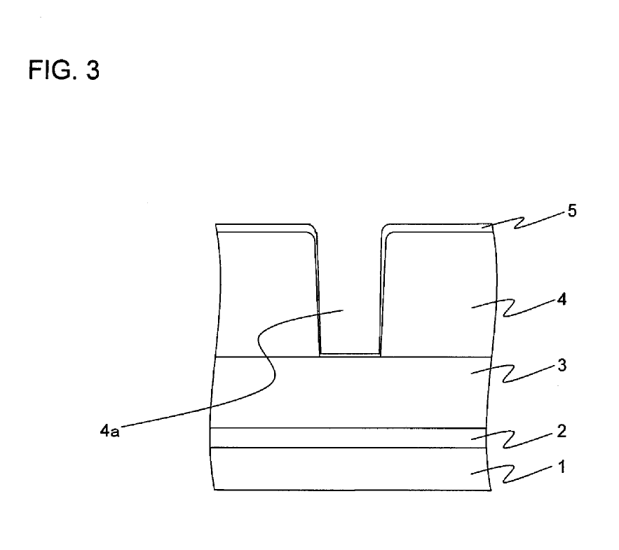

Thereafter, as shown in FIG. 3, barrier seed layer 5 made of Ti having a thickness of 20 nm is formed by a sputtering so as to cover an inner wall (a side wall and a bottom) of through-hole 4a. Barrier seed layer 5 covers not only the inner wall of hole 4a but also a surface of interlayer insulating layer 4 outside hole 4a. It is preferable that barrier seed layer 5 is sufficiently formed on the bottom of hole 4a and even that a thickness of barrier seed layer 5 formed on the side wall has minor variations. Barrier seed layer 5 is formed, for example, under following conditions: a target bias power: 20 to 40 KW (a power density: 17 to 34 W/cm²); a substrate bias power: 0 to 800 W (a power density: 0 to 1.1 W/cm²); and a film thickness: 10 to 30 nm. Direct current power may be used as the target bias power and high frequency power may be used as the substrate bias power.

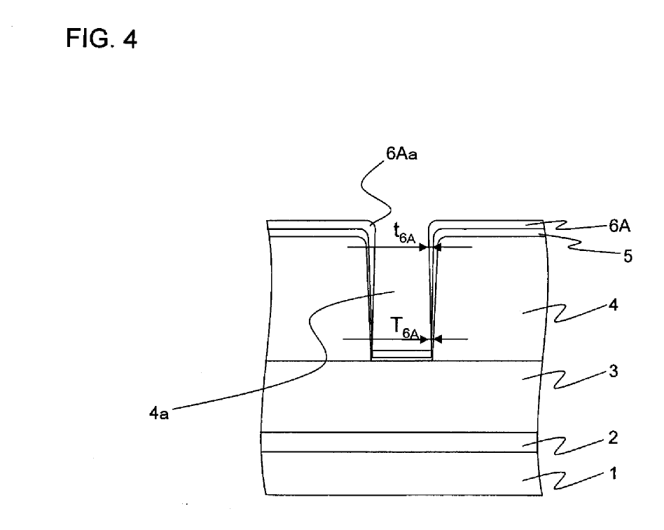

Next, as shown in FIG. 4, first barrier layer 6A made of TiN having a thickness of 15 nm is formed by a sputtering with a relatively low substrate bias power so as to cover an inner wall (a side wall and a bottom) of through-hole 4a. First barrier layer 6A covers not only the inner wall of hole 4a but also a surface of barrier seed layer 5 outside hole 4a. At this time, an overhang made of first barrier layer 6A is formed at the aperture of hole 4a and, hence, a diameter of the aperture turns out smaller. For this reason, it is difficult for sputtered ion species to enter into hole 4a and, hence, first barrier layer 6A is formed at a lower inner side wall of hole 4a with a less thickness than that at a upper inner side wall of hole 4a. First barrier layer 6A is formed, for example, under following conditions: a target bias power: 20 to 40 KW (a power density: 17 to 34 W/cm²); a substrate bias power: 0 to 800 W (a power density: 0 to 1.1 W/cm²); and a film thickness: 5 to 20 nm. Direct current power may be used as the target bias power and high frequency power may be used as the substrate bias power.

A thickness of first barrier layer 6A is set to 50% of a thickness of a barrier layer to be completed, so that while keeping a covering of first barrier layer 6A, a difference between a thickness t_{6A} of first barrier layer 6A at a top-side portion of the inner side wall of hole 4a and a thickness T_{6A} of first barrier layer 6A at a bottom-side portion of the inner side wall of hole 4a can be reduced as will appear below.

A comparison with regard to a thickness of TiN film within hole 4a was conducted between a compared example in which a thickness of TiN film formed outside hole 4a was 30 nm and a present example in which a thickness of TiN film formed outside hole 4a was 15 nm. In the compared example, the thickness t_{6A} of TiN film at a top-side portion of the inner side wall of hole 4a was 24 nm while in the present example, the thickness t_{6A} was 12 nm, and in the compared example, the thickness T_{6A} of TiN film at a bottom-side portion of the inner side wall of hole 4a was 16 nm while in the present example, the thickness T_{6A} was 8 nm, so that in the compared example, the difference of the thicknesses t_{6A}, T_{6A} becomes 8 nm (24-16) while in the present example, the difference of the thicknesses t_{6A}, T_{6A} becomes 4 nm (12-8), that is, the difference of the thicknesses t_{6A}, T_{6A} in the present example was smaller than that in the compared example.

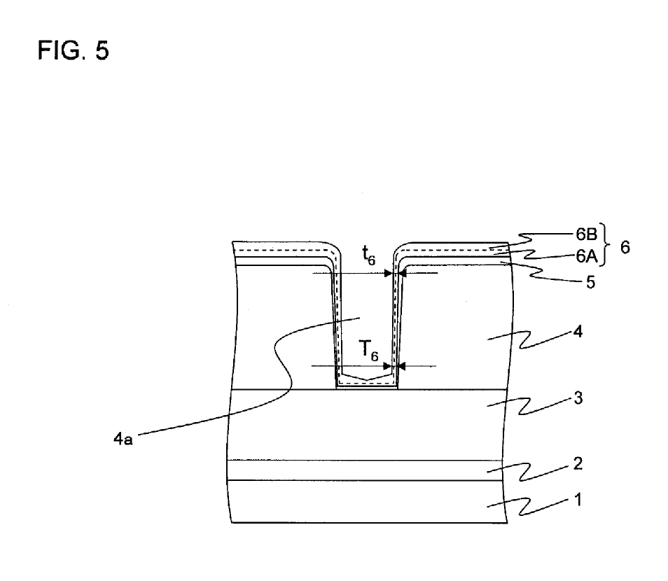

Subsequently, as shown in FIG. 5, second barrier layer 6B made of TiN having a thickness of 15 nm is formed by a sputtering with a substrate bias power that is higher than the substrate bias power used in forming first barrier layer 6A such that second barrier layer 6B covers an inner wall (a side wall and a bottom) of through-hole 4a. Second barrier layer 6B covers not only the inner wall of hole 4a but also a surface of first barrier layer 6A outside hole 4a. Here, a combination of first and second barrier layers 6A, 6B is called as barrier layer 6. Second barrier layer 6B is formed, for example, under following conditions: a target bias power: 20 to 40 KW (a power density: 17 to 34 W/cm²); a substrate bias power: 800 to 1500 W (a power density: 1.1 to 2.1 W/cm²); and a film thickness: 5 to 20 nm. Direct current power may be used as the target bias power and high frequency power may be used as the substrate bias power.

In forming second barrier layer 6B, a thickness thereof is set to 50% of a thickness of a barrier layer to be completed and, further, the used substrate bias power is higher than the substrate bias power used in forming first barrier layer 6A. When the substrate bias power becomes, in that way, higher, the ion species sputtered from a target of a film-forming apparatus have a strong directivity, so that the bottom coverage of hole 4a improves and, further, there occurs an effect of re-sputtering at a top-side portion in hole 4a. That is to say, ion species of TiN accelerated by the enhanced substrate bias power sputter the overhang 6Aa of first barrier layer 6A at the aperture of hole 4a, so that TiN is deposited at the inner wall (a side wall and a bottom) of hole 4a. In the same way, first barrier layer 6A at the bottom of hole 4a is sputtered and TiN is deposited at a side wall near the bottom. As a result, a thickness t₆ of barrier layer 6 at a top-side portion of the inner wall of hole 4a and a thickness T₆ of barrier layer 6 at a bottom-side portion of the inner wall of hole 4a both increase. Although first barrier layer 6A at the bottom of hole 4a is re-sputtered as mentioned above, second barrier layer 6B is selectively deposited by the enhanced substrate bias power, thereby obtaining a sufficient thickness of the barrier layer at the bottom.

A comparison with regard to a thickness of TiN film within hole 4a was conducted between a compared example in which a thickness of TiN film formed outside hole 4a was 30 nm and one sputtering step with a low bias was performed and a present example in which a thickness of TiN film formed outside hole 4a was 30 nm and two sputtering steps with low and high biases respectively were performed. In the compared example, the thickness of TiN film at a top-side portion of the inner side wall of hole 4a was 12 nm while in the present example, the thickness of TiN film at a top-side portion of the inner side wall of hole 4a was 17 nm, and in the compared example, the thickness of TiN film at a bottom-side portion of the inner side wall of hole 4a was 8 nm while in the present example, the thickness of TiN film at a bottom-side portion of the inner side wall of hole 4a was 27 nm.

Although both of ratios of thicknesses of first and second barrier layers 6A, 6B to a given film thickness was set to 50%, the present invention is not limited to such ratios but, rather, the ratios of thicknesses of first and second barrier layers 6A, 6B are appropriately adjusted according to a situation in which a desired barrier layer 6 is formed.

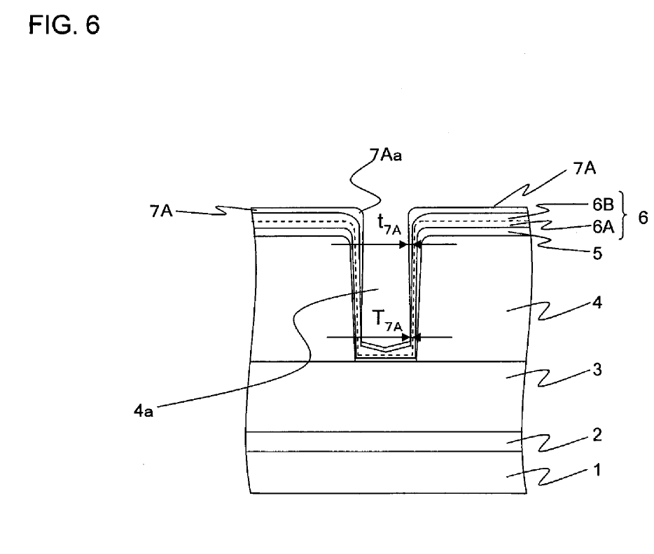

Next, as shown in FIG. 6, first wiring seed Ti layer 7A made of Ti having a thickness of 10 nm is formed by a sputtering with a relatively low substrate bias power so as to cover an inner wall (a side wall and a bottom) of through-hole 4a. First wiring seed Ti layer 7A covers not only the inner wall of hole 4a but also a surface of barrier layer 6 outside hole 4a. At this time, an overhang made of first wiring seed Ti layer 7A is formed at the aperture of hole 4a and, hence, a diameter of the aperture turns out smaller. For this reason, it is difficult for sputtered ion species to enter into hole 4a and, hence, first wiring seed Ti layer 7A is formed at a lower inner side wall of hole 4a with a less thickness than that at a upper inner side wall of hole 4a. First wiring seed Ti layer 7A is formed, for example, under following conditions: a target bias power: 20 to 40 KW (a power density: 17 to 34 W/cm²); a substrate bias power: 0 to 800 W (a power density: 0 to 1.1 W/cm²); and a film thickness: 5 to 20 nm. Direct current power may be used as the target bias power and high frequency power may be used as the substrate bias power.

A thickness of first wiring seed Ti layer 7A is set to 50% of a thickness of a wiring seed Ti layer to be completed, so that while keeping a covering of first wiring seed Ti layer 7A, a difference between a thickness t_{7A} of first wiring seed Ti layer 7A at a top-side portion of the inner side wall of hole 4a and a thickness T_{7A} of first wiring seed Ti layer 7A at a bottom-side portion of the inner side wall of hole 4a can be reduced as will appear below.

A comparison with regard to a thickness of Ti film within hole 4a was conducted between a compared example in which a thickness of Ti film formed outside hole 4a was 20 nm and a present example in which a thickness of Ti film formed outside hole 4a was 10 nm. In the compared example, the thickness t_{7A}, of Ti film at a top-side portion of the inner side wall of hole 4a was 16 nm while in the present example, the thickness t_{7A} was 8 nm, and in the compared example, the thickness T_{7A} of Ti film at a bottom-side portion of the inner side wall of hole 4a was 11 nm while in the present example, the thickness T_{7A} was 5.5 nm, so that in the compared example, the difference of the thicknesses t_{7A}, T_{7A} becomes 5 nm (16-11) while in the present example, the difference of the thicknesses t_{7A}, T_{7A} becomes 2.5 nm (8-5.5), that is, the difference of the thicknesses t_{7A}, T_{7A} in the present example was smaller than that in the compared example.

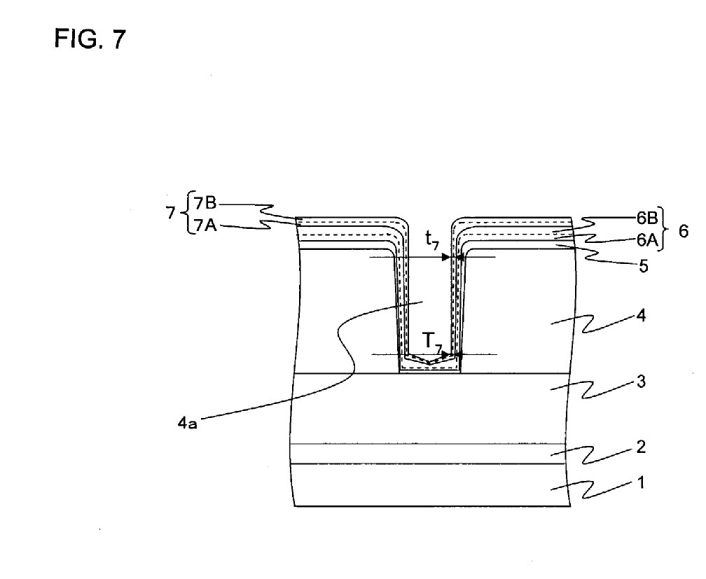

Subsequently, as shown in FIG. 7, second wiring seed Ti layer 7B made of Ti having a thickness of 10 nm is formed by a sputtering with a substrate bias power that is higher than the substrate bias power used in forming first wiring seed Ti layer 7A such that second wiring seed Ti layer 7B covers an inner wall (a side wall and a bottom) of through-hole 4a. Second wiring seed Ti layer 7B covers not only the inner wall of hole 4a but also a surface of first wiring seed Ti layer 7A outside hole 4a. Here, a combination of first and second wiring seed Ti layers 7A, 7B is called as wiring seed Ti layer 7. Second wiring seed Ti layer 7B is formed, for example, under following conditions: a target bias power: 20 to 40 KW (a power density: 17 to 34 W/cm²); a substrate bias power: 800 to 1500 W (a power density: 1.1 to 2.1 W/cm²); and a film thickness: 5 to 20 nm. Direct current power may be used as the target bias power and high frequency power may be used as the substrate bias power.

In forming second wiring seed Ti layer 7B, a thickness thereof is set to 50% of a thickness of a wiring seed Ti layer to be completed and, further, the used substrate bias power is higher than the substrate bias power used in forming first wiring seed Ti layer 7A. When the substrate bias power becomes, in that way, higher, the ion species sputtered from a target of a film-forming apparatus have a strong directivity, so that the bottom coverage of hole 4a improves and, further, there occurs an effect of re-sputtering at a top-side portion in hole 4a. That is to say, ion species of Ti accelerated by the enhanced substrate bias power sputter the overhang 7Aa of first wiring seed Ti layer 7A at the aperture of hole 4a, so that Ti is deposited at the inner wall (a side wall and a bottom) of hole 4a. In the same way, first wiring seed Ti layer 7A at the bottom of hole 4a is sputtered and Ti is deposited at a side wall near the bottom. As a result, a thickness t₇ of wiring seed Ti layer 7 at a top-side portion of the inner wall of hole 4a and a thickness T₇ of wiring seed Ti layer 7 at a bottom-side portion of the inner wall of hole 4a both increase. Although first wiring seed Ti layer 7A at the bottom of hole 4a is re-sputtered as mentioned above, second wiring seed Ti layer 7B is selectively deposited by the enhanced substrate bias power, thereby obtaining a sufficient thickness of the wiring seed Ti layer at the bottom.

A comparison with regard to a thickness of Ti film within hole 4a was conducted between a compared example in which a thickness of Ti film formed outside hole 4a was 20 nm and one sputtering step with a low bias was performed and a present example in which a thickness of Ti film formed outside hole 4a was 20 nm and two sputtering steps with low and high biases respectively were performed. In the compared example, the thickness of Ti film at a top-side portion of the inner side wall of hole 4a was 8 nm while in the present example, the thickness of Ti film at a top-side portion of the inner side wall was 11.5 nm, and in the compared example, the thickness of Ti film at a bottom-side portion of the inner side wall of hole 4a was 5.5 nm while in the present example, the thickness of Ti film at a bottom-side portion of the inner side wall of hole 4a was 18.5 nm.

Although both of ratios of thicknesses of first and second wiring seed Ti layers 7A, 7B to a given film thickness was set to 50%, the present invention is not limited to such ratios but, rather, the ratios of thicknesses of first and second wiring seed Ti layers 7A, 7B are appropriately adjusted according to a situation in which a desired wiring seed Ti layer 7 is formed.

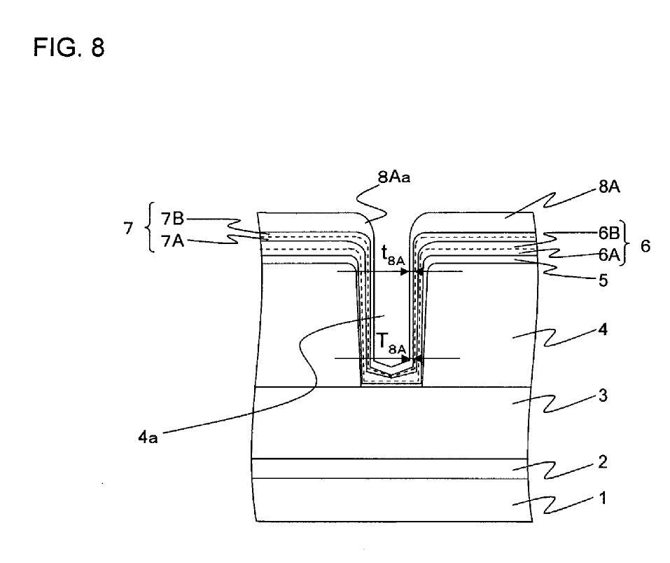

As a following step, as shown in FIG. 8, first wiring seed Al layer 8A made of Al having a thickness of 150 nm is formed by a sputtering with a relatively low substrate bias power so as to cover an inner wall (a side wall and a bottom) of through-hole 4a. First wiring seed Al layer 8A covers not only the inner wall of hole 4a but also a surface of a wiring seed Ti layer 7 outside hole 4a. At this time, an overhang made of first wiring seed Al layer 8A is formed at the aperture of hole 4a and, hence, a diameter of the aperture turns out smaller. For this reason, it is difficult for sputtered ion species to enter into hole 4a and, hence, first wiring seed Al layer 8A is formed at a lower inner side wall of hole 4a with a less thickness than that at a upper inner side wall of hole 4a. First wiring seed Al layer 8A is formed, for example, under following conditions: a target bias power: 30 to 40 KW (a power density: 20 to 27 W/cm²); a substrate bias power: 0 to 300 W (a power density: 0 to 0.42 W/cm²); and a film thickness: 100 to 300 nm. Direct current power may be used as the target bias power and high frequency power may be used as the substrate bias power.

A thickness of first wiring seed Al layer 8A is set to 50% of a thickness of a wiring seed Al layer to be completed, so that while keeping a covering of first wiring seed Al layer 8A, a difference between a thickness t_{8A} of first wiring seed Al layer 8A at a top-side portion of the inner side wall of hole 4a and a thickness T_{8A} of first wiring seed Al layer 8A at a bottom-side portion of the inner side wall of hole 4a can be reduced as will appear below.

A comparison with regard to a thickness of Al film within hole 4a was conducted between a compared example in which a thickness of Al film formed outside hole 4a was 300 nm and a present example in which a thickness of Al film formed outside hole 4a was 150 nm. In the compared example, the thickness t_{8A} of Al film at a top-side portion of the inner side wall of hole 4a was 120 nm while in the present example, the thickness t_{8A} was 60 nm, and in the compared example, the thickness T_{8A} of Al film at a bottom-side portion of the inner side wall of hole 4a was 80 nm while in the present example, the thickness T_{8A} was 40 nm, so that in the compared example, the difference of the thicknesses t_{8A}, T_{8A} becomes 40 nm (120-80) while in the present example, the difference of the thicknesses t_{8A}, T_{8A} becomes 20 nm (60-40), that is, the difference of the thicknesses t_{8A}, T_{8A} in the present example was smaller than that in the compared example.

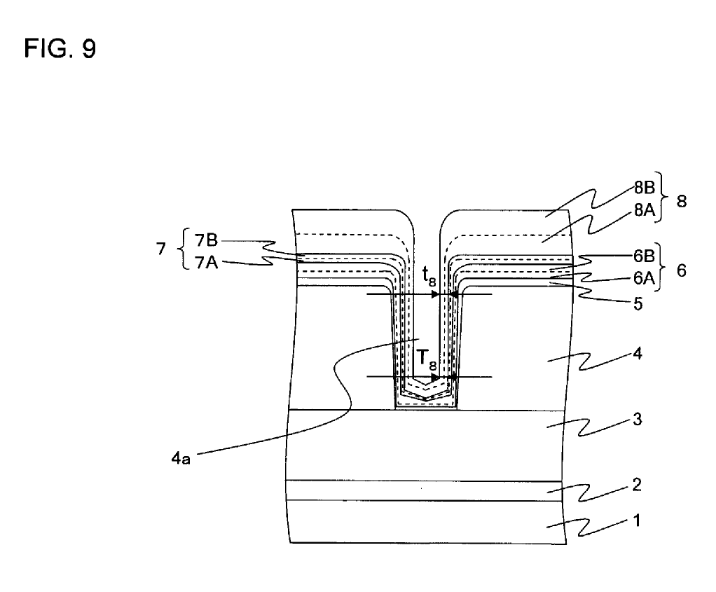

Subsequently, as shown in FIG. 9, second wiring seed Al layer 8B made of Al having a thickness of 150 nm is formed by a sputtering with a substrate bias power that is higher than the substrate bias power used in forming first wiring seed Al layer 8A such that second wiring seed Al layer 8B covers an inner wall (a side wall and a bottom) of through-hole 4a. Second wiring seed Al layer 8B covers not only the inner wall of hole 4a but also a surface of first wiring seed Al layer 8A outside hole 4a. Here, a combination of first and second wiring seed Al layers 8A, 8B is called as wiring seed Al layer 8. Second wiring seed Al layer 8B is formed, for example, under following conditions: a target bias power: 30 to 40 KW (a power density: 20 to 27 W/cm²); a substrate bias power: 500 to 1200 W (a power density: 0.7 to 1.7 W/cm²); and a film thickness: 100 to 300 nm. Direct current power may be used as the target bias power and high frequency power may be used as the substrate bias power.

In forming second wiring seed Al layer 8B, a thickness thereof is set to 50% of a thickness of a wiring seed Al layer to be completed and, further, the used substrate bias power is higher than the substrate bias power used in forming first wiring seed Al layer 8A. When the substrate bias power becomes, in that way, higher, the ion species sputtered from a target of a film-forming apparatus have a strong directivity, so that the bottom coverage of hole 4a improves and, further, there occurs an effect of re-sputtering at a top-side portion in hole 4a. That is to say, ion species of Al accelerated by the enhanced substrate bias power sputter the overhang 8Aa of first wiring seed Al layer 8A at the aperture of hole 4a, so that Al is deposited at the inner wall (a side wall and a bottom) of hole 4a. In the same way, first wiring seed Al layer 8A at the bottom of hole 4a is sputtered and Al is deposited at a side wall near the bottom. As a result, a thickness t₈ of wiring seed Al layer 8 at a top-side portion of the inner side wall of hole 4a and a thickness T₈ of wiring seed Al layer 8 at a bottom-side portion of the inner side wall of hole 8a both increase. Although first wiring seed Al layer 8A at the bottom of hole 4a is re-sputtered as mentioned above, second wiring seed Al layer 8B is selectively deposited by the enhanced substrate bias power, thereby obtaining a sufficient thickness of the wiring seed Al layer at the bottom.

A comparison with regard to a thickness of Al film within hole 4a was conducted between a compared example in which a thickness of Al film formed outside hole 4a was 300 nm and one sputtering step with a low bias was performed and a present example in which a thickness of Al film formed outside hole 4a was 300 nm and two sputtering steps with low and high biases respectively were performed. In the compared example, the thickness of Al film at a top-side portion of the inner side wall of hole 4a was 60 nm while in the present example, the thickness of Al film at a top-side portion of the inner side wall of hole 4a was 85 nm, and in the compared example, the thickness of Al film at a bottom-side portion of the inner side wall of hole 4a was 40 nm while in the present example, the thickness of Al film at a bottom-side portion of the inner side wall of hole 4a was 135 nm.

Although both of ratios of thicknesses of first and second wiring seed Al layers 8A, 8B to a given film thickness was set to 50%, the present invention is not limited to such ratios but, rather, the ratios of thicknesses of first and second wiring seed Al layers 8A, 8B are appropriately adjusted according to a situation in which a desired wiring seed Al layer 8 is formed.

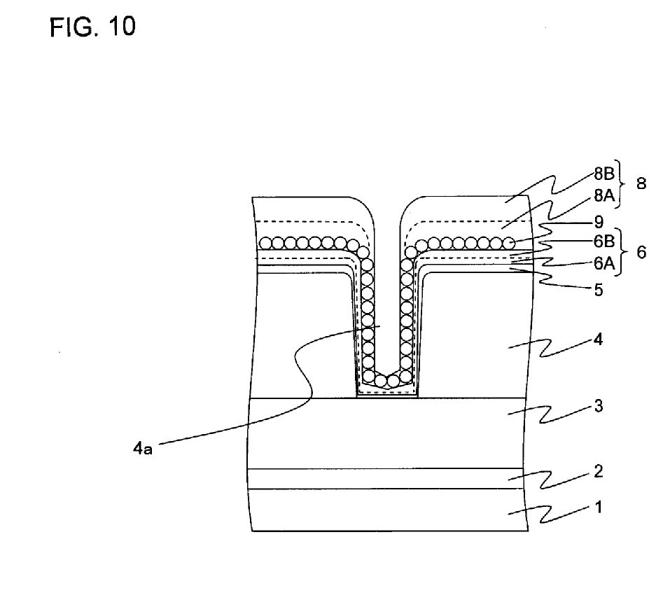

Subsequently, the resultant structure is subjected to a thermal treatment at 380 to 450° C. during 30 to 120 seconds and, thus, Ti of wiring seed Ti layer 7 and Al of wiring seed Al layer 8 are reacted each other, so that as shown in FIG. 10, Ti—Al alloy particles 9 are generated at an interface of the two layers. Because at this time, a thickness of wiring seed Al layer 8 within hole 4a is small (for example, when a thickness of wiring seed Al layer 8 on wiring seed Ti layer 7 outside hole 4a is 300 nm, a thickness of wiring seed Al layer 8 on wiring seed Ti layer 7 within hole 4a is 85-135 nm), Ti—Al alloy particles 9 are generated such that surfaces thereof are exposed within hole 4a (although growth of the alloy particles are substantially completed at this step, growth thereof are possible by heating at next steps). Because Ti—Al alloy particles 9 are wetted very well to Al which is material of reflow Al layer 10 to be formed at a next step, Ti—Al alloy particles 9 cause Al to be easily filled into hole 4a. Because in this exemplary embodiment, wiring seed Ti layer 7 and wiring seed Al layer 8 are formed within hole 4a with a uniform thickness, Ti—Al alloy particles 9 are formed within hole 4a with a regular distribution (further, Ti—Al alloy particles 9 are sufficiently formed at the bottom of hole 4a), so that Al is sufficiently filled into hole 4a. Although Ti—Al alloy particles 9 are shown as uniformly circular in the figure, Ti—Al particles 9, in practice, have rock-shaped indeterminate forms and the sizes thereof have minor variations.

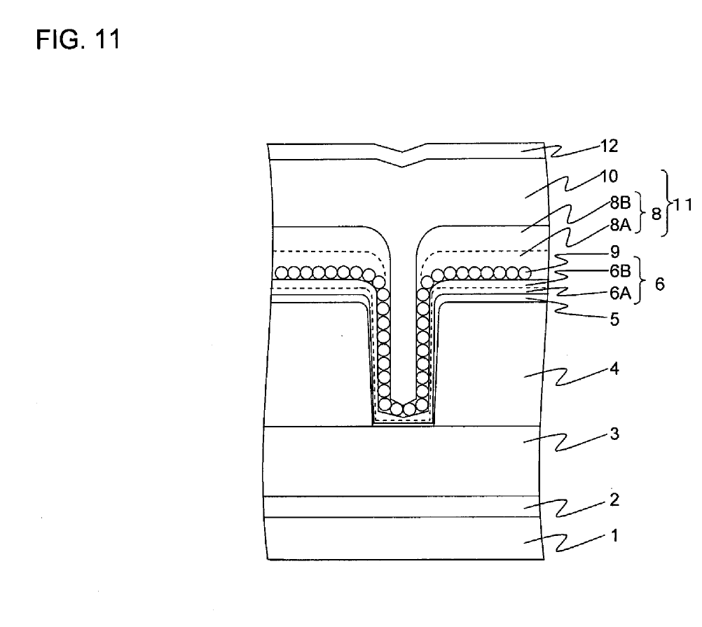

Next, as shown in FIG. 11, reflow Al layer 10 made of Al having a thickness of 700 nm is formed so as to cover an inner wall (a side wall and a bottom) of through-hole 4a by a reflow sputtering method in which a sputtering is conducted while a substrate is heated. At this time, reflow Al layer 10 and wiring seed Al layer 8 are integrated into one body and, hence, a combination of reflow Al layer 10 and wiring seed Al layer 8 is called as Al wiring 11. Reflow Al layer 10 is formed so as to cover not only the inner wall of hole 4a but also a surface of second wiring seed Al layer 8B outside hole 4a. Reflow Al layer 10 is formed, for example, under following conditions: a target bias power: 1 to 25 KW (a power density: 0.66 to 17 W/cm²); a substrate bias power: 0; substrate temperature: 380 to 450° C.; and a film thickness: 300 to 1000 nm.

Because as mentioned above, Ti—Al alloy particles 9 which are wetted very well to Al are formed within hole 4a with a regular distribution, reflow Al layer 10 can be reliably filled into hole 4a.

As a following step, cap film 12 made of TiN having a thickness of 25 nm as an anti-reflection layer is formed on Al wiring 11 by a sputtering. Cap film 12 is formed, for example, under following conditions: a target bias power: 10 to 20 KW (a power density: 8 to 16 W/cm²); a substrate bias power: 0; and a film thickness: 10 to 50 nm.

Thereafter, predetermined processes for manufacturing a semiconductor device including a process of forming a metallization, etc are carried out by usual methods.

In the present exemplary embodiment, the barrier layer is formed by the first step using a low bias and the second step using a high bias. For this reason, the coverage of the barrier layer especially in the bottom of the hole improves and, hence, a thickness of the barrier layer in the bottom in the present exemplary embodiment can be 3 times as large as that in the compared example in which the barrier layer is formed by one step. Consequently, the diffusion of Al resulting from thinning of the barrier layer at the bottom of the hole can be suppressed. In particular, when Al wiring is connected to Cu wiring, Al—Cu alloy with high electrical resistance is prevented from being formed and, hence, a signal transfer delay or a discontinuation in the wirings can be avoided.

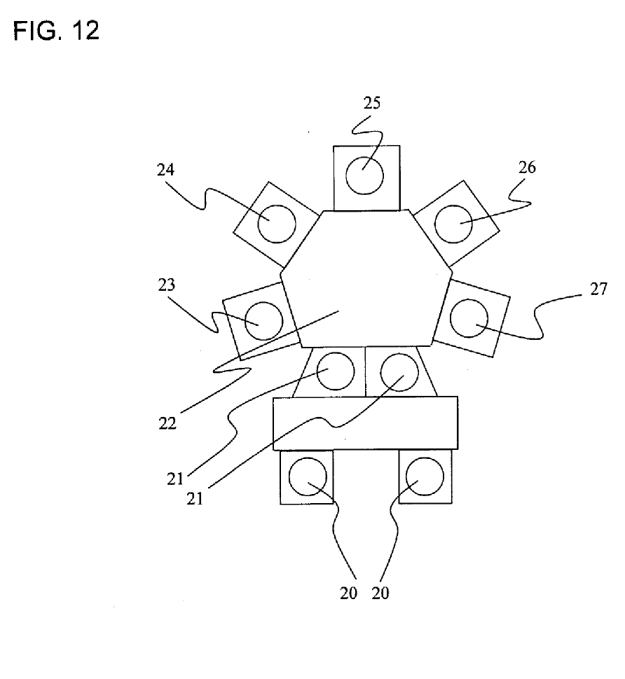

FIG. 12 shows a plan view for illustrating a film-forming apparatus used in the manufacturing method according to the exemplary embodiment. This film-forming apparatus has a multi-chamber configuration in which 5 treatment chambers kept at a vacuum state are interconnected around conveying area 22. A wafer comes to a standstill in load port 20 of a wafer container (FOUP: Front Open Unified Pod or FOSB: Front Opening Shipping Box) and, then, is transferred to load-lock chamber 21 installed to prevent each of the treatment chambers from being open to the atmosphere. A pressure of load-lock chamber 21 is lowered so as to have the same vacuum level as that of each treatment chamber. Thereafter, the wafer in load-lock chamber 21 is conveyed to each treatment chamber, in which the wafer is subjected to a single wafer process as follows.

First, each wafer is conveyed to wafer annealing chamber 23 using a conveying unit and is subjected to an annealing treatment under hydrogen atmosphere one at a time, and, thus, a natural oxidation film formed on a region of Cu wiring which is exposed at the bottom of the through-hole is removed. Next, the wafer is conveyed to film-forming chamber 24 in which barrier seed layer 5, barrier layer 6 (first barrier layer 6A, second barrier layer 6B) and wiring seed Ti layer 7 (first wiring seed Ti layer 7A, second wiring seed Ti layer 7B) are formed in the order described. Subsequently, the wafer is, in a clockwise direction, transferred to film-forming chambers 25, 26, 27 in the order described, in which wiring seed Al layer 8 (first wiring seed Al layer 8A, second wiring seed Al layer 8B), reflow Al layer 10 and cap film 12 are formed, respectively. Here, in film-forming chamber 26, before reflow Al layer 10 is formed, Al—Ti alloy particles 9 are generated by heating substrate 1.

With regard to the film-forming apparatus, the wafer is kept in any one of the chambers until the film-forming process is completed and, hence, the film-forming process is carried out while the wafer is not exposed to the atmosphere and its surface film is not naturally oxidized. In this manner, degradation of film adhesion due to formation of the natural oxidation film can be suppressed.

In this sputtering treatment, Ar is used as an ion source to collide against the target and pressures of the chambers are set to a depressurized condition of a usual sputtering method. The wiring seed Al layer and reflow Al layer may employ as their materials a usual aluminum wiring material including aluminum or aluminum alloy, etc. The Cu wiring may employ as its material a usual copper wiring material including copper or copper alloy, etc. Although the present exemplary embodiment has been applied to the through-hole, the present invention may be applied to various shapes of recesses or depressed portions such as a trench.

It is apparent that the present invention is not limited to the above embodiments, but may be modified and changed without departing from the scope and spirit of the invention.

What is claimed is:

1. A method for manufacturing a semiconductor device, comprising:
forming a recess in an insulating film on a substrate;
forming a barrier seed Ti layer covering an inner wall of the recess;
forming, by a sputtering, a first barrier TiN layer covering the barrier seed Ti layer in the recess;
forming a second barrier TiN layer on the first barrier TiN layer by a sputtering with a substrate bias power higher than a substrate bias power used in forming the first barrier TiN layer;
forming, by a sputtering, a first wiring seed Ti layer covering the second barrier TiN layer in the recess;
forming a second wiring seed Ti layer on the first wiring seed Ti layer by a sputtering with a substrate bias power higher than a substrate bias power used in forming the first wiring seed Ti layer;
forming, by a sputtering, a first wiring seed Al layer covering the second wiring seed Ti layer in the recess;
forming a second wiring seed Al layer on the first wiring seed Al layer by a sputtering with a substrate bias power higher than a substrate bias power used in forming the first wiring seed Al layer;
forming, by a heating, Ti—Al alloy on the second barrier TiN layer in the recess; and
forming an Al wiring material layer covering the recess so as to fill the recess with the Al wiring material layer by sputtering and heating for reflowing the Al wiring material layer.

2. The method according to claim 1, wherein the Ti—Al alloy is formed so as to be exposed in the recess.

3. The method according to claim 1, further comprising forming a copper wiring material layer beneath the insulating film, wherein the recess is formed on the copper wiring material layer so as to expose the copper wiring material layer.

4. The method according to claim 1, wherein the recess is a through-hole penetrating the insulating film.

5. The method according to claim 4, wherein a diameter of an aperture of the through-hole is equal to or less than 0.5 μm, and a depth of the through-hole is equal to or less than 2.5 μm, and an aspect ratio of the through-hole is in a range of 1 to 5.

6. The method according to claim 1, wherein each of the substrate bias powers is a high frequency power.

7. The method according to claim 1, wherein in forming the first barrier TiN layer, a density of a target bias power is set within a range of 17 to 34 W/cm² and a density of the substrate bias power is set within a range of 0 to 1.1 W/cm²;
in forming the second barrier TiN layer, a density of a target bias power is set within a range of 17 to 34 W/cm² and a density of the substrate bias power is set within a range of 1.1 to 2.1 W/cm²;
in forming the first wiring seed Ti layer, a density of a target bias power is set within a range of 17 to 34 W/cm² and a density of the substrate bias power is set within a range of 0 to 1.1 W/cm²;
in forming the second wiring seed Ti layer, a density of a target bias power is set within a range of 17 to 34 W/cm² and a density of the substrate bias power is set within a range of 1.1 to 2.1 W/cm²;
in forming the first wiring seed Al layer, a density of a target bias power is set within a range of 20 to 27 W/cm² and a density of the substrate bias power is set within a range of 0 to 0.42 W/cm²; and
in forming the second wiring seed Al layer, a density of a target bias power is set within a range of 20 to 27 W/cm² and a density of the substrate bias power is set within a range of 0.7 to 1.7 W/cm².

8. The method according to claim 7, wherein in forming the first and second barrier TiN layers, the first and second wiring seed Ti layers and the first and second wiring seed Al layers, each of the target bias powers is a direct current power and each of the substrate bias powers is a high frequency power.
